(19) United States
(12) Patent Application Publication
(10) Pub. No.: US 2003/0143811 A1
(43) Pub. Date: Jul. 31, 2003

(54) Method for radiation hardening N-channel MOS transistors

(76) Inventors: Joseph Benedetto, Monument, CO (US); Anthony Jordan, Colorado Springs, CO (US); Robert Bauer, Monument, CO (US)

Correspondence Address: HOGAN & HARTSON LLP, ONE TABOR CENTER, SUITE 1500, 1200 SEVENTEENTH ST, DENVER, CO, 80202, US

(21) Appl. No.: 10/360,099

(22) Filed: Feb. 7, 2003

Related U.S. Application Data
(62) Division of application No. 09/930,043, filed on Aug. 15, 2001.

(51) Int. Cl. H01L 21/336

(52) U.S. Cl. 438/294

(57) ABSTRACT

An N-channel radiation-hardened transistor has source and drain regions that are fully enclosed by an intrinsically radiation-hardened thin gate-oxide. which substantially reduces radiation-induced intra-device and inter-device leakage currents. The width of the polysilicon gate directly between the source and drain can be the minimum feature size allowed by the design rules of a given process. The width of the polysilicon surrounding the device is chosen by design rules from the minimum allowed to some wider value to allows the polysilicon overlap to be sufficient to self-align the source and drain without compromising the doping under the field region. The polysilicon should be sufficiently wide so that it completely overlaps any transitional oxide such as LOCOS or trench oxide. The gate capacitance of the N-channel transistor can be tuned to balance SEU hardness and switching performance. An alternative radiation-hardened transistor for high-current applications includes an annular transistor design in which the transistor is completely surrounded with a thin gate oxide to substantially reduce radiation-induced inter-device leakage currents.

### BACKGROUND OF THE INVENTION

This invention relates generally to radiation-hardened transistors, and, more specifically, to a structure and method of improving the radiation hardening of manufacturable integrated circuit N-channel transistors.

It is commonly known that N-channel transistors manufactured on a metal-oxide-semiconductor (MOS) process are vulnerable to ionizing radiation. The effects are well documented and include threshold-voltage shifts, transconductance degradation and intra-device and inter-device leakage paths. It is also well known that a thin oxide is less susceptible to ionizing radiation than a thick oxide. Because of the shift to extremely thin (<10 nm) gate oxides in modem transistor fabrication facilities, many of the ionizing radiation-induced degradation effects have all but disappeared. N-channel intra-device and inter-device leakage currents remain as the only significant vulnerability in commercial complementary MOS (CMOS) processes.

Referring now to FIG. 1 a typical CMOS structure 10 is shown including a P-well 12 and an N-well 14. N+ active regions 16, 18, and 20 are diffused into P-well 12 and include N+ source and drain regions. P+ active regions 22, 24, and 26 are diffused in N-well 14 and include P+ source and drain regions. N+ active regions 16, 18, and 20 and P+ active regions 22, 24, and 26 are typically surrounded by a thick field oxide isolation 28. Gate structures 30, 32, 34, 36, and 38 cross over the active regions to form the separate source and drain regions in the respective wells 12 and 14. Representative intra-device leakage paths 40 and 42 form a channel between the N+ source and drain regions of N+ active region 20. Representative inter-device leakage path 44 forms a channel between N+ active region 16 and N+ active region 18. Note that in FIG. 1, the leakage paths are within and between the N+ regions and not the P+ regions because ionizing radiation produces trapped holes in these regions, which consequently only form channels in the N+ regions.

A number of techniques have been developed, with varying degrees of success, to mitigate the intra-device and inter-device leakage current problem illustrated in FIG. 1. One popular design technique for eliminating leakage paths is the annular, or closed-geometry, transistor 50 shown in FIG. 2. FIG. 2 shows a typical implementation 50 of an annular design. Note that the drain 48 and source 54 are completely isolated from each other by the thin oxide of an annular gate 52. The thin oxide is not visible in the plan view of FIG. 2, but underlies the polysilicon gate 52. Although the design shown in FIG. 2 is successful at eliminating the intra-device leakage path, the inter-device leakage path still remains. Further, while transistor 50 is suitable for use in high-current applications, it is difficult to use in high-density integrated circuit designs because of the large effective width and corresponding low packing density of the device. Another drawback of transistor 50 is that polysilicon contacts must be made into the center of the device, further limiting integration density.

What is desired, therefore, is a method and device structure for an N-channel transistor that is hardened to the effects of ionizing radiation, yet suitable for use in a densely packed integrated circuit layout.

### SUMMARY OF THE INVENTION

According to a first embodiment of the present invention, a radiation-hardened transistor has source and drain regions that are fully enclosed at the periphery thereof by an intrinsically radiation-hardened thin gate-oxide and optional polysilicon layer, which substantially reduces radiation-induced intra-device and inter-device leakage currents. The width of the polysilicon gate directly between the source and drain can be the minimum feature size allowed by the design rules of a given process. The width of the polysilicon surrounding the device is chosen by design rules from the minimum allowed to some wider value to allows the polysilicon overlap to be sufficient to self-align the source and drain without compromising the doping under the field region. The polysilicon overlap, if used, should be sufficiently wide so that it completely overlaps any transitional oxide such as LOCOS or trench oxide.

Certain embodiments of the present invention include an additional gate capacitance. In some applications, such as an SEU-hard latch design, this extra capacitance is beneficial. In other design applications, however, the extra capacitance is not desirable and so other embodiments of the present invention the extra gate capacitance is reduced. The N-channel transistor of the present invention can be “tuned” to provide the proper balance between SEU hardness and extra gate capacitance. This “tuning” can be accomplished in a commercial semiconductor fabrication facility and requires no special processing equipment. The tuned N-channel transistor requires only a single additional processing sequence: a masking step and polysilicon etch.

In a second embodiment of the radiation-hardened transistor of the present invention, a prior art annular transistor design is completely surrounded with a thin gate oxide and optional polysilicon layer to substantially reduce radiation-induced inter-device leakage currents.

It is an advantage of a first embodiment of the present invention that the novel transistor design completely eliminates the need to fully enclose the source by the drain, or vice versa, as in the prior art radiation-hardened annular transistor.

It is a further advantage of a first embodiment of the present invention that all of the integration penalties associated with the prior art annular transistor design such as over-drive, poor transistor matching, and large size are eliminated.

It is a further advantage of the present invention that the transistor design is highly manufacturable and fully compatible with any modern semiconductor fabrication facility.

It is another advantage of the present invention that no changes are required to be made to a commercial semiconductor fabrication process, thus enabling a 1 Mrad(Si) integrated circuit (IC) to be manufactured on what is normally a 10 krad(Si) line.

It is a feature of the present invention that a radiation tolerance exceeding 1 Mrad(Si) of total ionizing dose is achieved.

It is another feature of the present invention that both intra-device and inter-device leakage currents are substantially reduced if not eliminated.

It is another feature of the present invention that extra gate capacitance makes the device less susceptible to single event upset (SEU) occurrences.

The foregoing and other objects, features and advantages of the invention will become more readily apparent from the following detailed description of a preferred embodiment of the invention, which proceeds with reference to the accompanying drawings.

### BRIEF DESCRIPTION OF THE DRAWINGS

FIG. 1 is a plan view of a prior art CMOS layout including representative radiation-induced inter-device and intra-device leakage paths;

FIG. 2 is a plan view of a prior art radiation-hardened N-channel annular transistor in which the drain and source are separated by an annular gate region;

FIG. 3 is a plan view of an N-channel transistor according to the present invention in which the source and drain regions of the transistor are surrounded by an intrinsically radiation-hard thin gate oxide;

FIG. 4 is a plan view of the N-channel transistor of FIG. 3 in which a portion of the gate region is removed and a single rectangular polysilicon gate defines the active gate region between the source and drain regions;

FIG. 5 is a plan view of the N-channel transistor of FIG. 3 in which a portion of the gate region is removed to reveal an H-shaped polysilicon gate region;

FIG. 6A is a cross-sectional view of a conventional MOS transistor;

FIG. 6B is a cross-sectional view of a radiation-hardened transistor according to the present invention corresponding to the plan views of FIGS. 3-5;

FIG. 7A is a cross-sectional view of a conventional MOS transistor including trench isolation;

FIG. 7B is a cross-sectional view of a radiation-hardened transistor according to the present invention including trench isolation;

FIG. 8 is a plan view of a radiation-hardened annular transistor according to the present invention further including an annular thin gate oxide structure for reducing radiation-induced inter-device leakage current; and

FIG. 9 is a cross-sectional view of a radiation-hardened annular transistor structure corresponding to the plan view of FIG. 8.

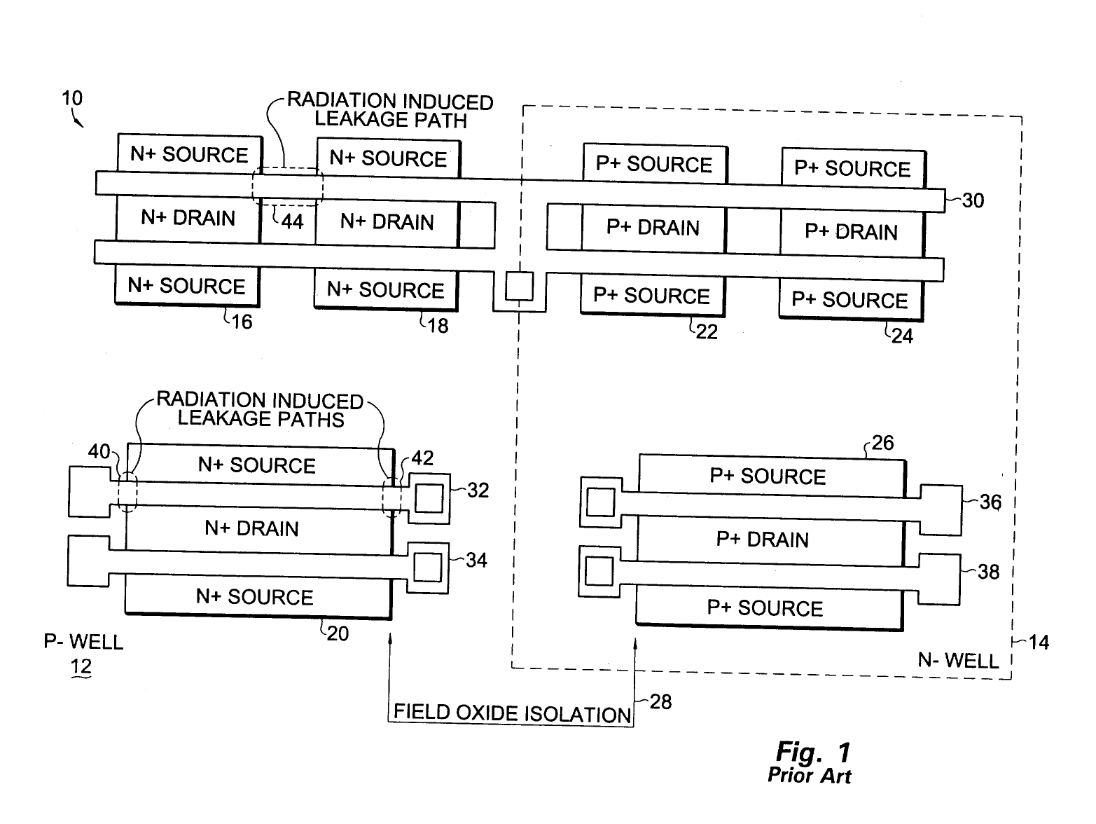

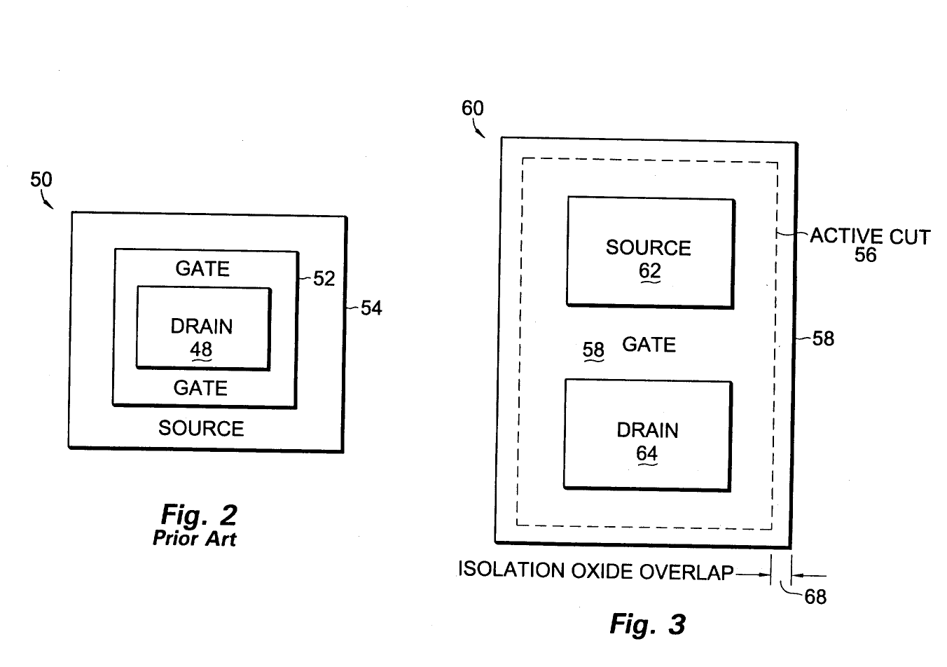

### DETAILED DESCRIPTION

Referring now to FIG. 3, a radiation-hardened transistor 60 includes a P-type silicon well or substrate defined by the active cut perimeter 56. The active cut 56 defines the boundary between a thin oxide radiation isolation layer and a thick oxide or trench isolation. An N-type source region 62 and an N-type drain region 64 are formed within the P-type substrate. A gate region 58 containing a polysilicon gate layer and a thin oxide layer is formed between the source and drain regions 62 and 64. The polysilicon gate layer is typically about 2000 Angstroms thick and the thin oxide layer is about 80 Angstroms thick. The gate region 58 overlaps the active cut 56 and surrounds the entire transistor 60. The isolation oxide overlap 68 is typically 0.25 to 0.60 μm wide, but the precise amount of overlap 68 is dependent upon the design rules of the process used. Minimum feature sizes can be used up to some wider amount of overlap of the isolation regions. Generally, minimum design rules are used, however there is no detriment to the radiation hardness using a wider overlap for better isolation. The thin gate-oxide layer of gate region 58 acts as a radiation isolation region surrounding source and drain regions 62 and 64 and extends up to the dimensions defined by the active cut perimeter 56. The thin gate oxide layer serves as an effective radiation isolation region that is intrinsically relatively impervious to the undesirable effects of ionizing radiation as long as the thickness of the oxide layer is kept less than about 150 Angstroms, with a desirable range being between about 60 and 150 Angstroms.

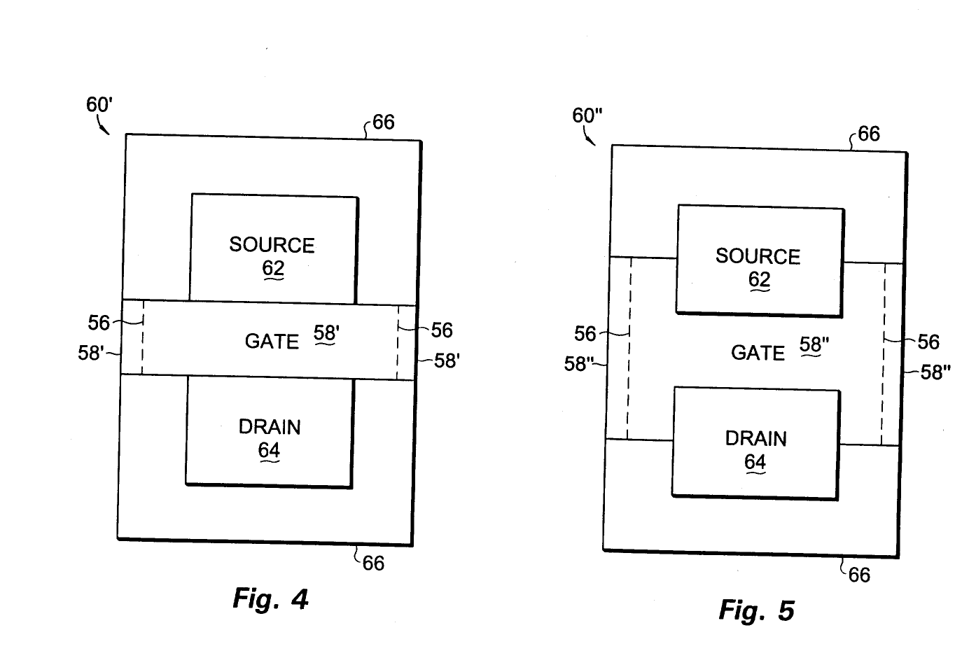

FIG. 4 shows transistor 60′ in which the entire polysilicon gate layer is removed except for that portion necessary to retain transistor action. Specifically, cross-hatched portions 66 represent the portions of the polysilicon gate layer that are removed from the layout of transistor 60 shown in FIG. 3. It is important to note that in FIG. 4, none of the thin gate oxide layer is removed. The thin gate oxide layer remains as before in transistor 60 and is defined by the perimeter of active cut 56. Thus the polysilicon portion of gate 58′ that remains is a rectangular shape as shown in FIG. 4 between the source and drain regions 62 and 64 and extending to the full lateral dimensions of transistor 60′, and overlapping active cut 56.

While all of the additional capacitance shown in the structure of FIG. 3 is removed, transistor 60′ still has enough polysilicon gate area to maintain transistor action. Notice that while all of the additional capacitance of the polysilicon layer of FIG. 3 is removed, transistor 60′ is still capable of mitigating radiation-induced leakage currents because the N-type source and drain regions 62 and 64 are completely enclosed by P-type silicon under a thermal thin-gate oxide layer defined by active cut 56. The final radiation hardness is dependent on the thin-oxide reflow glass stack. In many cases, the reflow glass traps both holes and electrons, making the device potentially hard to 1 Mrad(Si).

It is important to note that in transistors 60 and 60′ a parasitic channel still forms under the isolation thick oxides, however there is no possible conduction path from the source to the drain except by passing under the thin gate oxide layer, which is intrinsically radiation hardened. The entire transistor is thus radiation hardened and is only limited by the intrinsic hardness of the thin gate oxide layer used.

Referring now to FIG. 5, transistor 60″ is a variation of transistor 60 including an “H-shaped” gate region 58″, in which the gate capacitance can be tuned for optimizing SEU (single event upset) performance. SEU performance, transistor speed, and transistor power are traded-off in deciding the exact amount of capacitance required. A large gate region 58″ improves SEU performance, but reduces transistor speed or requires more power to maintain a desired level of speed/frequency performance. In FIG. 5, crosshatched portions 66 indicate the areas in which the polysilicon gate layer is removed, leaving the H-shaped gate region 58″. Again, it is important to note that the underlying gate oxide layer defined by active cut 56 is not changed. The radiation hardness of transistor 60″ is the same as that for transistors 60 and 60′ previously described and the radiation performance is only limited by the radiation hardness of the thin gate oxide layer used.

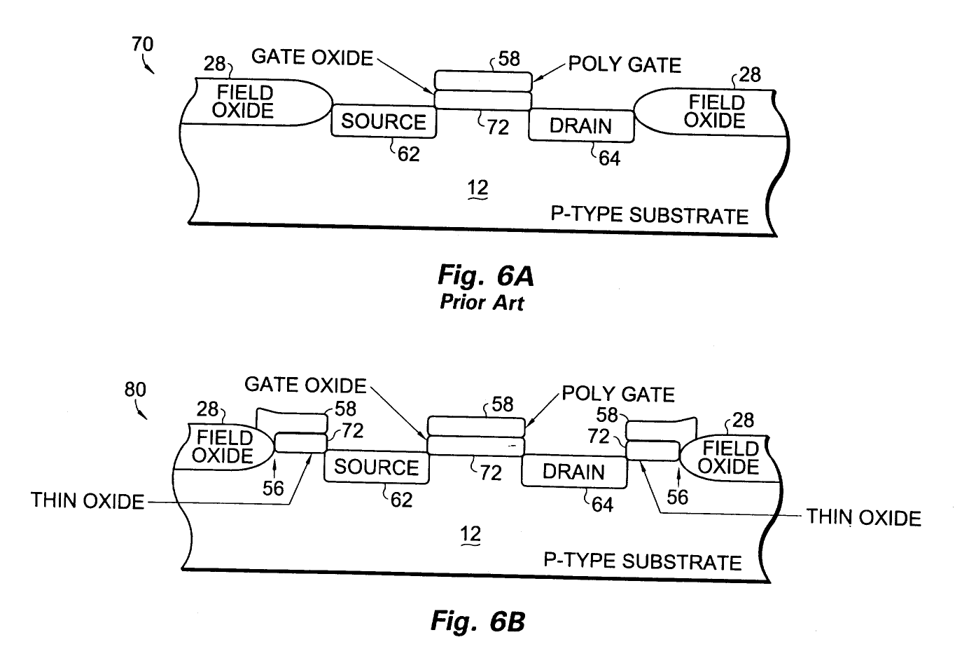

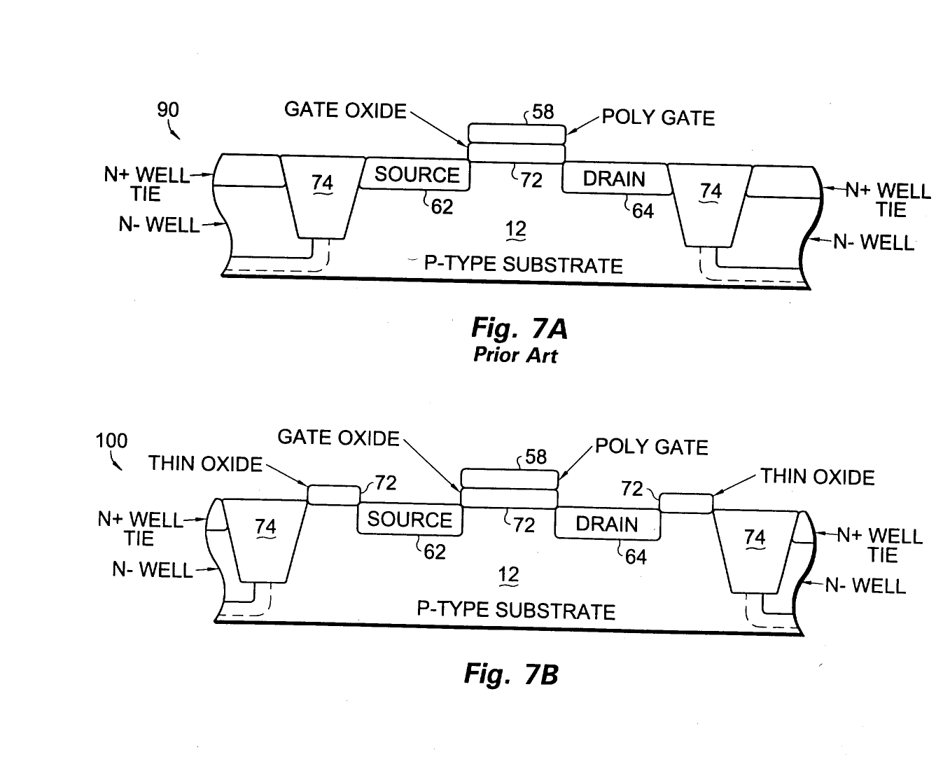

The present invention can be even better understood with reference to the cross-sectional FIGS. 6A, 6B, 7A, and 7B, which serve to reinforce the above description and to reveal further device structural details.

In FIG. 6A a cross-sectional diagram of a prior art non-radiation-hardened transistor 70 is shown having a P-type substrate or well 12, N-type source and drain regions 62 and 64, and thick field oxide isolation areas 28. The gate includes thin gate oxide layer 72 and a polysilicon gate 58. Transistor 70 is susceptible to leakage currents induced by ionizing radiation as previously described.

In FIG. 6B a cross-sectional diagram of a radiation-hardened transistor 80 according to the present invention is shown corresponding generally to the plan views of transistors 60, 60′ and 60″ shown in FIGS. 3, 4, and 5. Transistor 80 includes a thin oxide layer 72 that is used both for the gate oxide and for the radiation isolation surrounding the source and drain regions 62 and 64. A polysilicon gate layer 58 is used for the conductive portion of the gate contact and also to overlap active cuts 56 as required by transistors 60 and 60″ shown in FIGS. 3 and 5. Polysilicon overlap layer 58 is not required by transistor 60′ shown in FIG. 4.

In FIG. 7A a cross-sectional diagram of a prior art non-radiation-hardened transistor 90 is shown having shallow trench isolation including oxide in which the isolation is provided by trenches 74 and not thick field oxide. Transistor 100 in FIG. 7B shows an embodiment of the radiation-hardened transistor of the present invention including the thin oxide radiation isolation layer 72, and isolation from trenches 74.

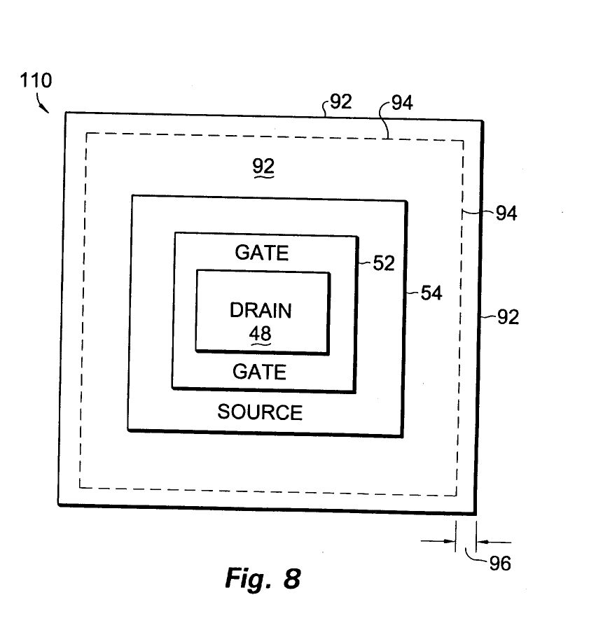

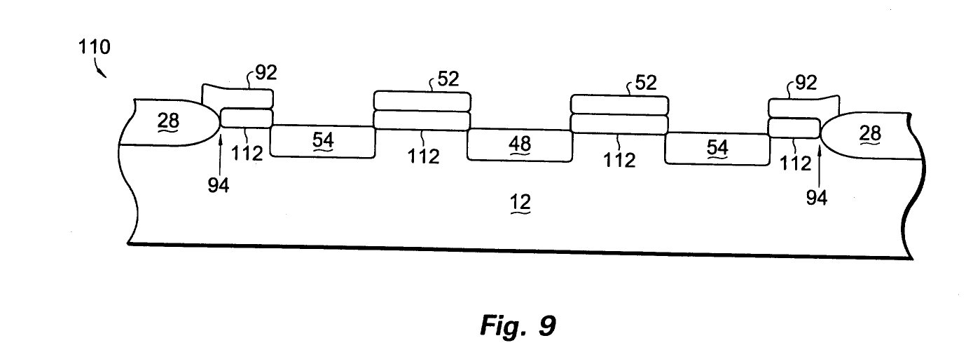

Finally, FIG. 8 shows a second embodiment of the radiation-hardened transistor of the present invention useful for high current applications while substantially reducing or eliminating radiation-induced inter-device leakage current. Radiation-hardened transistor 110 includes a P-type well or substrate, and an N-channel drain region 48 formed within the substrate. An annular gate region 52 surrounds the drain region including a thin gate oxide and polysilicon gate layers. An N-type source region 54 surrounds the gate region 52. In addition, an additional polysilicon region 92 and a thin gate oxide region extending to the active cut 94 surrounds source region 54. Thus polysilicon region 92 overlaps active cut 94. Polysilicon region 92 may therefore be partially or completely etched away depending upon the nature of the SEU performance required.

Having described and illustrated the principle of the invention in a preferred embodiment thereof, it is appreciated by those having skill in the art that the invention can be modified in arrangement and detail without departing from such principles. For example, various layout spacings and layer thicknesses can be changed as desired for a particular application. We therefore claim all modifications and variations coming within the spirit and scope of the following claims.

I claim:

1. A radiation-hardened transistor comprising:
a substrate;
a source region formed within the substrate;
a drain region formed within the substrate;
a gate region formed between the source and drain regions; and
a thin gate oxide radiation isolation region surrounding the source and drain regions.

2. A radiation-hardened transistor as in claim 1 further comprising an additional gate region laterally overlapping the thin gate oxide isolation.

3. A radiation-hardened transistor as in claim 1 in which the gate region comprises an H-shaped gate region.

4. A radiation-hardened transistor as in claim 1 in the which the substrate comprises a P-type substrate.

5. A radiation-hardened transistor as in claim 1 in which the source region comprises an N-type source region.

6. A radiation-hardened transistor as in claim 1 in which drain region comprises an N-type drain region.

7. A radiation-hardened transistor as in claim 1 in which the gate region comprise a thin gate oxide and a polysilicon gate.

8. A radiation-hardened transistor as in claim 1 in which the thin gate oxide radiation isolation region comprises a layer of oxide between about 60 and 150 Angstroms thick.

9. A radiation-hardened transistor as in claim 1 further comprising a thick field oxide surrounding the thin gate oxide radiation isolation region.

10. A radiation-hardened transistor as in claim 1 further comprising a shallow trench isolation surrounding the thin gate oxide radiation isolation region.

11. A radiation-hardened transistor comprising:
a substrate;
a drain region formed within the substrate;
a gate region surrounding the drain region;
a source region surrounding the gate region; and
a thin gate oxide radiation isolation region surrounding the source region.

12. A radiation-hardened transistor as in claim 11 further comprising an additional gate region laterally overlapping the thin gate oxide isolation.

13. A radiation-hardened transistor as in claim 11 in which the gate region comprises an additional O-shaped gate region.

14. A radiation-hardened transistor as in claim 11 in the which the substrate comprises a P-type substrate.

15. A radiation-hardened transistor as in claim 11 in which the source region comprises an N-type source region.

16. A radiation-hardened transistor as in claim 11 in which drain region comprises an N-type drain region.

17. A radiation-hardened transistor as in claim 11 in which the gate region comprise a thin gate oxide and a polysilicon gate.

18. A radiation-hardened transistor as in claim 11 in which the thin gate oxide radiation isolation region comprises a layer of oxide between about 60 and 150 Angstroms thick.

19. A radiation-hardened transistor as in claim 11 further comprising a thick field oxide surrounding the thin gate oxide radiation isolation region.

20. A radiation-hardened transistor as in claim 11 further comprising a shallow trench isolation surrounding the thin gate oxide radiation isolation region.

21. A method of radiation-hardening an N-channel transistor comprising surrounding the periphery of the transistor with a thin-gate oxide layer extending to a thick field or trench oxide capable of preventing radiation-induced inter-device and intra-device leakage current up to an ionizing dosage of about 1 Mrad(Si).
